(19) United States
(12) Patent Application Publication
(10) Pub. No.: US 2025/0364885 A1
(43) Pub. Date: Nov. 27, 2025

(54) INVERTER CONTROL DEVICE USING MULTICHANNEL SEQUENCER AND DATA PROCESSING METHOD OF MULTICHANNEL SEQUENCER

(71) Applicant: HYUNDAI AUTOEVER CORP., Seoul (KR)

(72) Inventors: Eun Su Jun, Seoul (KR); Dong Hui Lim, Seoul (KR)

(73) Assignee: HYUNDAI AUTOEVER CORP., Seoul (KR)

(21) Appl. No.: 19/214,998

(22) Filed: May 21, 2025

(30) Foreign Application Priority Data
May 22, 2024 (KR) 10-2024-0066549

(51) Int. Cl. H02M 1/00; H02M 1/08

(52) U.S. Cl. CPC H02M 1/0012; H02M 1/08

(57) ABSTRACT

An inverter control apparatus includes a core configured to calculate a switching pulse-width modulation (PWM) control value by using an analog-to-digital converter (ADC) sampling value for an inverter, store the switching PWM control value in a new-data variable in a shared memory, and increment a data counter. The inverter control apparatus also includes a multichannel sequencer configured to, when the value of the data counter is different from a value of a previous-data counter, store the value of the new-data variable in a buffer-data variable and store the value of the data counter in the previous-data counter, and update a register with a value of the buffer-data variable or a value of a previous-data variable that stores a previous value of the buffer-data variable. The inverter control apparatus includes a PWM control circuit configured to output a switching PWM signal that controls the inverter using a value of the register.

### CROSS-REFERENCE TO RELATED APPLICATION

This application claims the benefit of and priority to Korea Patent Application No. 10-2024-0066549, filed on May 22, 2024, the entire contents of which are hereby incorporated herein by reference.

### FIELD OF TECHNOLOGY

The present disclosure relates to an inverter.

### BACKGROUND

Inverters are apparatuses that convert electric power. The primary function of these apparatuses is to convert direct current (DC) power to alternating current (AC) power. Inverters play an essential role in applications such as photovoltaic power generation, electric vehicle charging infrastructure, uninterruptible power supplies (UPSs), and general household electrical equipment. DC power is typically generated in photovoltaic panels or storage devices such as batteries. This generated DC power is converted via an inverter into AC power suitable for use in homes or businesses. Voltage regulation also occurs during this process, and low-voltage DC is stepped up to high-voltage AC to supply power according to user requirements. Inverter technology is crucial for improving energy efficiency, minimizing power loss, and enabling a stable power supply.

Inverters convert DC voltage to AC voltage via pulse-width modulation (PWM) control. An inverter typically includes six power semiconductor switches, which are commonly insulated-gate bipolar transistors (IGBTs) or metal-oxide-semiconductor field-effect transistors (MOSFETs). These semiconductors are precisely controlled to receive a voltage and convert the received voltage into an AC voltage.

A PWM control method involves generating an AC voltage with a desired voltage and frequency by adjusting the operating time of each switch. Here, the switches adjust the width of a signal (where a wider signal corresponds to a higher voltage and a narrower signal corresponds to a lower voltage) by turning on and off at significantly high speeds. This process is used to synthesize a desired waveform, such as a sine wave, ultimately enabling an efficient and precise power supply.

The inverter senses an output current, an output voltage, and an input voltage via an analog-to-digital converter (ADC), and then uses this data to calculate a PWM duty cycle for the next switching period. Sensors connected to the inverter sense changes in current and voltage as analog signals, which are then converted into digital data via the ADC. Through this conversion, an inverter control apparatus obtains real-time data enabling precise power regulation.

The digitally converted voltage-current data is processed by the inverter control apparatus. During this processing, an optimal PWM duty cycle is calculated based on input power conditions. The PWM duty cycle determines the duration for which the power semiconductor switches within the inverter remain turned on, and this is used to adjust the waveform, frequency, and phase of the converted AC voltage.

The inverter may perform ADC sensing once per switching period, subsequently execute calculations for controlling the next switching period, and then set the calculation result in a register. When more precise control is required, the inverter may perform ADC sensing twice per switching period. This is also referred to as double sampling.

However, applying such double sampling to an inverter reduces the margin of a control load factor, and when a control interrupt service routine (ISR) is delayed, situations may arise where ensuring data coherency becomes difficult.

The discussions in this section are intended merely to provide background information and do not constitute an admission of prior art.

### SUMMARY

An embodiment of the present disclosure provides an inverter control technology capable of ensuring data coherency in any case. In another aspect, the present disclosure provides a data processing technology capable of ensuring data coherency in an inverter performing double sampling.

According to an embodiment, an inverter control apparatus is provided. The inverter control apparatus includes a core configured to execute a calculation logic that calculates a switching pulse-width modulation (PWM) control value by using an analog-to-digital converter (ADC) sampling value for an inverter, and a data sharing logic that stores the switching PWM control value in a new-data variable within a shared memory and then increments a data counter. The inverter control apparatus also includes a multichannel sequencer configured to execute a data obtaining logic that, while checking a value of the data counter and when the value of the data counter is different from a value of a previous-data counter, stores the value of the new-data variable in a buffer-data variable and stores the value of the data counter in the previous-data counter, and an update logic that updates a register with a value of the buffer-data variable or a value of the previous-data variable that stores a previous value of the buffer-data variable. The inverter control apparatus additionally includes a PWM control circuit configured to output a switching PWM signal that controls the inverter by using a value within the register.

The multichannel sequencer may divide each switching PWM period into a first control period and a second control period, and execute the update logic in a predetermined time interval of each of the first control period and the second control period.

When the core executes the calculation logic once in each switching PWM period, the update logic may update, in the first control period, the register with the value of the previous-data variable, and update, in the second control period, the register with the value of the buffer-data variable.

The multichannel sequencer may execute the update logic once in each control period, and execute the data obtaining logic by using a polling technique in which the value of the data counter is checked at regular time intervals.

The data sharing logic may, when storing the switching PWM control value in the new-data variable, set a value of a status variable, which is located in the shared memory, to a first value, the data obtaining logic may, when storing the value of the new-data variable in the buffer-data variable, set the value of the status variable to a second value, and the update logic may, when the value of the status variable is the first value, update the register with the value of the previous-data variable, and when the value of the status variable is the second value, update the register with the value of the buffer-data variable.

The update logic may, when the value of the status variable is the first value, set a data-obtaining flag to a third value, and the data obtaining logic may check both the value of the data counter and the value of the data-obtaining flag, and when the value of the data counter is different from the value of the previous-data counter, and the value of the data-obtaining flag is different from the third value, store the value of the new-data variable in the buffer-data variable.

The multichannel sequencer may execute a flag management logic that sets the value of the data-obtaining flag to a fourth value that is different from the third value.

The multichannel sequencer may divide each switching PWM period into a first control period and a second control period, and execute the flag management logic within a predetermined time period from a start time point of each control period.

The update logic may, when the value of the status variable is the first value, set a set-previous-data flag to a seventh value, and the multichannel sequencer may, when the set-previous-data flag is the seventh value, execute a set-previous-data logic that stores the value of the buffer-data variable in the previous-data variable.

According to another embodiment, another inverter control apparatus is provided. The inverter control apparatus includes a core configured to divide each switching PWM period into a first control period and a second control period, and execute, in each control period, a calculation logic that calculates a switching PWM control value by using an ADC sampling value for an inverter, and a data sharing logic that stores the switching PWM control value in a new-data variable within a shared memory. The inverter control apparatus also includes a multichannel sequencer configured to execute a data obtaining logic that stores a value of the new-data variable in a buffer-data variable, and an update logic that updates a register in a predetermined update interval in each control period, wherein when a time point of updating the new-data variable is earlier than a start time point of the update interval, the update logic updates the register with a value of the buffer-data variable, and when the time point of updating the new-data variable is later than the start time point of the update interval, the update logic updates the register with a value of a previous-data variable storing a previous value of the buffer-data variable. The inverter control apparatus additionally includes a PWM control circuit configured to output a switching PWM signal that controls the inverter by using a value within the register.

The multichannel sequencer may, when the update logic updates the register with the value of the previous-data variable, execute the data obtaining logic in a next control period.

The multichannel sequencer may, when the update logic updates the register with the value of the previous-data variable, execute a set-previous-data logic that stores the value of the buffer-data variable in the previous-data variable, in a corresponding update interval.

The core may increment a data counter after the data sharing logic stores the switching PWM control value in the new-data variable within the shared memory, and the multichannel sequencer may determine the time point of updating the new-data variable, by comparing the value of the data counter with a value of a previous-data counter that stores a previous value of the data counter.

The multichannel sequencer may execute the update logic once in each control period, and execute the data obtaining logic by using a polling technique in which the value of the data counter is checked at regular time intervals.

According to yet another embodiment, a method of multichannel sequencing in an inverter control apparatus is provided. The method may be implemented by a multichannel sequencer included in an inverter control apparatus that outputs a switching PWM signal that controls an inverter by using a value within a register. The data processing method includes checking a data counter that is incremented by a core configured to calculate a switching PWM control value by using an ADC sampling value for the inverter, wherein the data counter is incremented after the core stores the switching PWM control value in a new-data variable of a shared memory. The method also includes, when a value of the data counter is different from a value of a previous-data counter, storing a value of the new-data variable in a buffer-data variable and storing the value of the data counter in the previous-data counter. The method additionally includes updating the register with a value of the buffer-data variable or a value of a previous-data variable that stores a previous value of the buffer-data variable.

Each switching PWM period may be divided into a first control period and a second control period, a predetermined update interval is allocated to each control period, and in the update interval, the register may be updated with the value of the buffer-data variable or the value of the previous-data variable.

When the core obtains the ADC sampling value only once in each switching PWM period, updating the register may include updating, in the first control period, the register with the value of the previous-data variable, and updating, in the second control period, the register with the value of the buffer-data variable.

As described above, according to an embodiment of the present disclosure, an inverter may maintain data coherency in any case. Furthermore, according to an embodiment of the present disclosure, data coherency may be ensured in an inverter in which double sampling is performed.

### BRIEF DESCRIPTION OF THE DRAWINGS

FIG. 1 is a diagram illustrating a general inverter performing single-sampling control by using a single core.

FIG. 2 is a diagram illustrating a general inverter performing double-sampling control by using a single core.

FIG. 3 is a diagram illustrating a problem that may arise when a general inverter performs double-sampling control by using a single core.

FIG. 4 is a diagram illustrating a first example of performing single-sampling control in an inverter, according to an embodiment.

FIG. 5 is a diagram illustrating a first example of performing double-sampling control in an inverter, according to an embodiment.

FIG. 6 is a diagram illustrating a second example of performing single-sampling control in an inverter, according to an embodiment.

FIG. 7 is a diagram illustrating a second example of performing double-sampling control in an inverter, according to an embodiment.

FIG. 8 is a diagram illustrating a third example of performing double-sampling control in an inverter, according to an embodiment.

FIG. 9 is a configuration diagram of an inverter control apparatus according to an embodiment.

FIG. 10 is a flowchart of a data sharing logic according to an embodiment.

FIG. 11 is a flowchart of a data obtaining logic according to an embodiment.

FIG. 12 is a flowchart of an update logic according to an embodiment.

FIG. 13 is a flowchart of a flag management logic according to an embodiment.

FIG. 14 is a flowchart of a previous-data setting logic according to an embodiment.

FIG. 15 is a flowchart of a data processing method of a multichannel sequencer according to an embodiment.

### DETAILED DESCRIPTION

Hereinafter, some embodiments of the present disclosure are described in detail with reference to the accompanying drawings. It should be noted that in assigning reference numerals to components in the accompanying drawings, identical components are designated by the same reference numerals whenever possible, even when the components are illustrated in different drawings. Furthermore, in the description of the present disclosure, where it was determined that a detailed description of related known configurations or functions would obscure the gist of the present disclosure, such the detailed description thereof has been omitted.

In addition, in describing components of the present disclosure, expressions such as “first”, “second”, “A”, “B”, “(a)”, or “(b)” may be used. These expressions are only intended to distinguish one component from another, and do not limit the nature, order, or sequence of the components. It should be understood that, when it is described that a first element is “connected,” “coupled,” or “joined” to a second element, the first element may be directly connected, coupled, or joined to the second element, or the first element may be connected, coupled, or joined to the second element with a third element connected, coupled, or joined therebetween.

When a component, controller, device, element, apparatus, unit, logic, or the like of the present disclosure is described as having a purpose or performing an operation, function, or the like, the component, controller, device, element, apparatus, unit, logic or the like should be considered herein as being “configured to” meet that purpose or to perform that operation or function. Each component, controller, device, element, apparatus, unit, and the like may separately embody or be included with a processor and a memory, such as a non-transitory computer readable media, as part of the apparatus.

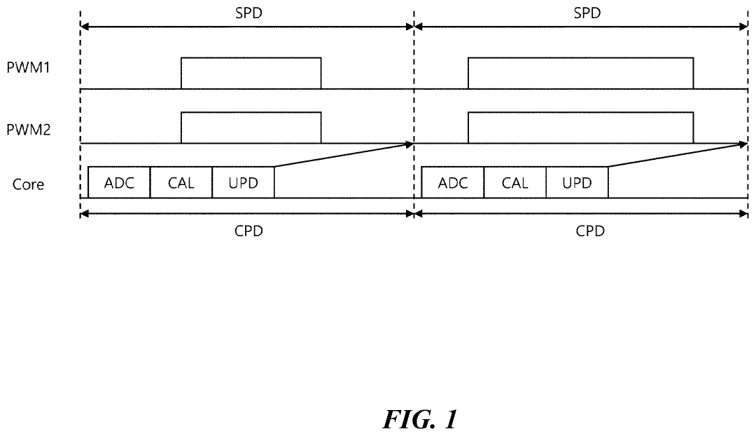

FIG. 1 is a diagram illustrating a general inverter performing single-sampling control by using a single core.

Referring to FIG. 1, the inverter may perform analog-to-digital converter (ADC) sensing once within each switching period SPD (ADC).

The inverter may then calculate control parameters based on obtained ADC sensing data (CAL). For example, the inverter may calculate a rising edge value and/or a falling edge value for determining a pulse-width modulation (PWM) duty cycle. Alternatively, the inverter may calculate a PWM duty cycle value and may also calculate other modified values.

The inverter may update a storage with the calculated control value (UPD). Here, the storage may be a register. The inverter may store the rising edge value in a control mode (CM) register or in another register. Such calculation of the control value and updating of the register may be performed by a core.

In addition, a driver for generating a PWM signal may generate a PWM signal by comparing a value stored in the register with a comparison value (e.g., a counter value) (PWM1 and PWM2).

A period during which the inverter performs PWM control may be referred to as the switching period SPD. An interval during which the control value is updated may be referred to as a control period CPD. In a general inverter performing single-sampling control, the switching period SPD and the control period CPD may have the same duration.

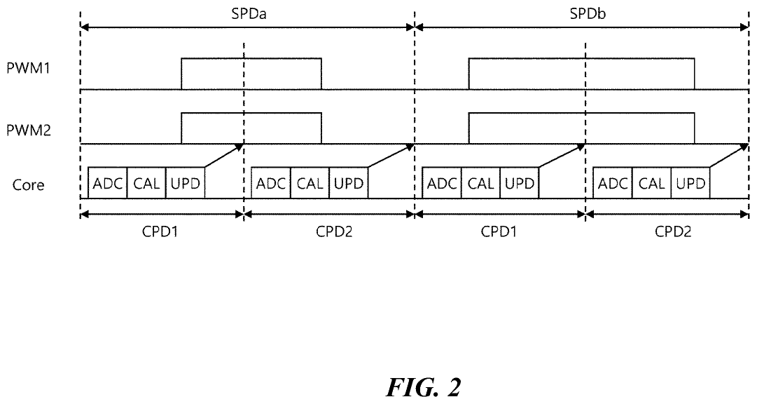

FIG. 2 is a diagram illustrating a general inverter performing double-sampling control by using a single core.

Referring to FIG. 2, the inverter may divide each switching period SPDa or SPDb into two control periods CPD1 and CPD2, may perform ADC sensing in each of the control periods CPD1 and CPD2 (ADC), may calculate a control value based on ADC sensing data (CAL), and may update a storage with the control value (UPD).

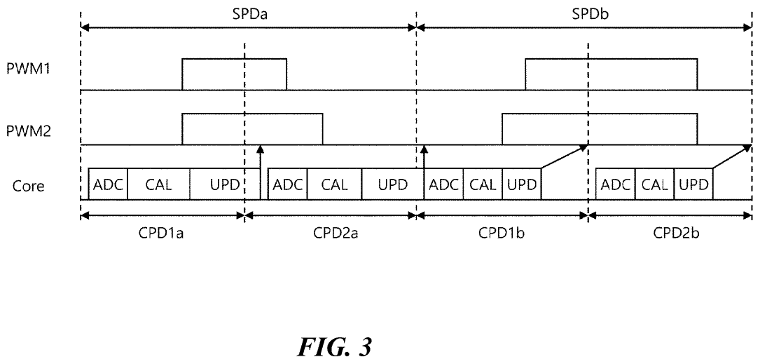

FIG. 3 is a diagram illustrating a problem that may arise when a general inverter performs double-sampling control by using a single core.

Referring to FIG. 3, when the time required for the core of the inverter to calculate the control value based on the ADC sensing data (CAL), or the time required to update the storage with the control value (UPD), is prolonged, the time point of updating the storage with the control value may exceed the end time point of one control period. For example, referring to FIG. 3, it may be observed that updates are not completed within a first control period CPD1a and a second control period CPD1b of the first switching period SPDa.

In such a case, the calculated control value may be applied not in the intended control period but in a subsequent control period, which may compromise data coherency.

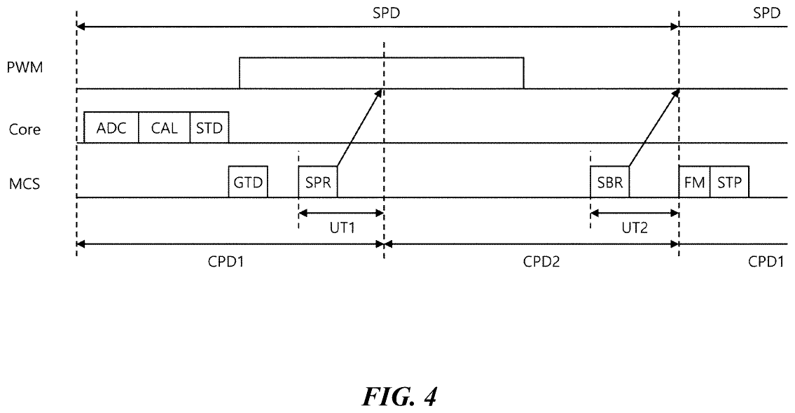

FIG. 4 is a diagram illustrating a first example of performing single-sampling control in an inverter, according to an embodiment.

Referring to FIG. 4, the inverter may perform data processing in a distributed manner between a core and a multichannel sequencer (MCS). This combination of the core and the MCS may be referred to as an inverter control apparatus.

The core may calculate a switching PWM control value by using an ADC sampling value for the inverter (CAL).

Then, the core may store the calculated switching PWM control value in a variable within a shared memory (STD). The variable stored in the shared memory may be referred to as a new-data variable.

One switching period SPD may be divided into two control periods CPD1 and CPD2. The core may repeatedly perform ADC, CAL, and STD in each of the control periods CPD1 and CPD2.

In the first control period CPD1, the MCS may store, in a buffer-data variable, a value stored in the new-data variable within the shared memory (GTD).

In a first update interval UT1 that is set within the first control period CPD1, the MCS may update a storage (e.g., a register; hereinafter, for convenience of description, ‘storage’ is sometimes referred to as ‘register’) with the value of a previous-data variable (SPR). Here, the previous-data variable refers to a variable that stores a previous value of the buffer-data variable.

In a second update interval UT2 that is set within the second control period CPD2, the MCS may update the register with the value of the buffer-data variable (SBR).

In the first control period CPD1, the MCS may execute a flag management logic FM. The flag management logic FM, according to an embodiment, is described in more detail below.

In addition, in the first control period CPD1, the MCS may store, in the previous-data variable, the value of the buffer-data variable (STP).

The MCS may operate based on a polling method. The MCS may update the register in the predetermined update intervals UT1 and UT2, within the control periods CPD1 and CPD2, respectively. Accordingly, even when the calculation time of the core is prolonged, data coherency may be ensured.

Furthermore, by separating the buffer-data variable and the previous-data variable, the inverter control apparatus according to an embodiment may be applied to both single sampling and double sampling.

In addition, by performing data processing in a distributed manner between the core and the MCS, problems in data processing caused by processing time delays in the core may also be mitigated.

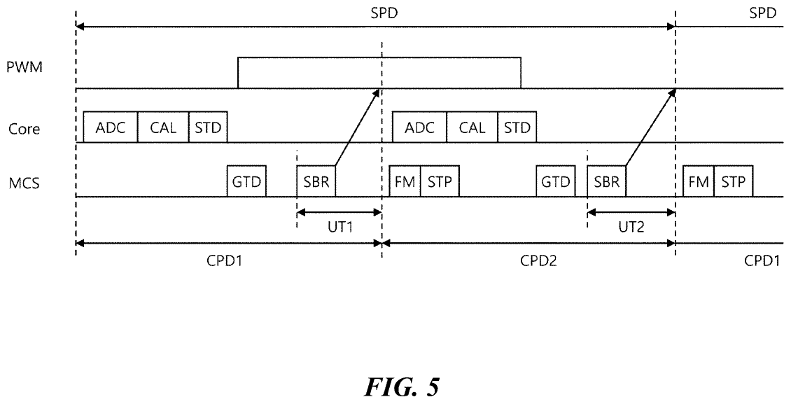

FIG. 5 is a diagram illustrating a first example of performing double-sampling control in an inverter, according to an embodiment.

Referring to FIG. 5, the core may calculate a switching PWM control value by using an ADC sampling value for the inverter (CAL). Then, the core may store the calculated switching PWM control value in the new-data variable within the shared memory (STD).

One switching period SPD may be divided into two control periods CPD1 and CPD2. In addition, the core may repeatedly perform ADC, CAL, and STD in each of the control periods CPD1 and CPD2.

In the first control period CPD1, the MCS may store, in the buffer-data variable, a value stored in the new-data variable within the shared memory (GTD).

In a first update interval UT1 that is set within the first control period CPD1, the MCS may update the register with the value of the buffer-data variable (SBR).

In the second control period CPD2, the MCS may store, in the buffer-data variable, the value stored in the new-data variable within the shared memory (GTD), and in a second update interval UT2 that is set within the second control period CPD2, the MCS may update the register with the value of the buffer-data variable (SBR).

In addition, in each of the control periods CPD1 and CPD2, the MCS may execute the flag management logic FM and may store, in the previous-data variable, the value of the buffer-data variable (STP).

The MCS may operate based on a polling method. The MCS may update the register in the predetermined update intervals UT1 and UT2, within the control periods CPD1 and CPD2, respectively. Accordingly, even when the calculation time of the core is prolonged, data coherency may be ensured.

Furthermore, by separating the buffer-data variable and the previous-data variable, the inverter control apparatus according to an embodiment may be applied to both single sampling and double sampling.

In addition, by performing data processing in a distributed manner between the core and the MCS, problems in data processing caused by processing time delays in the core may also be mitigated.

In some cases, due to a calculation time delay or a data storage delay in the core, the operation of the MCS may not be performed as described in the first example. In such a case, the MCS according to an embodiment may perform, in the reverse order, the operation of storing, in the buffer-data variable, the value stored in the new-data variable within the shared memory (GTD), and the operation of storing, in the previous-data variable, the value of the buffer-data variable (STP).

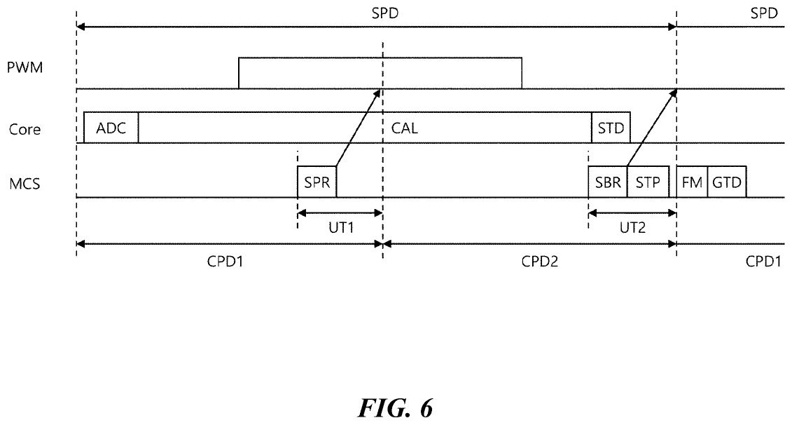

FIG. 6 is a diagram illustrating a second example of performing single-sampling control in an inverter, according to an embodiment.

Referring to FIG. 6, the core may calculate a switching PWM control value by using an ADC sampling value for the inverter (CAL). Here, when the duration of this switching PWM control value calculation operation (CAL) is prolonged, the time point of completion of the operation in which the core stores the switching PWM control value in the new-data variable within the shared memory (STD) may occur later than the start time point of the second update interval UT2.

In this case, the MCS may first update the register with the value of the buffer-data variable (SBR), in the second update interval UT2. In addition, the MCS may perform, within the second update interval UT2, the operation of storing the value of the buffer-data variable in the previous-data variable (STP), without first performing the operation of storing, in the buffer-data variable, the value stored in the new-data variable within the shared memory (GTD).

After performing the flag management logic FM, the MCS may perform the operation of storing, in the buffer-data variable, the value stored in the new-data variable within the shared memory (GTD). In this manner, even when the calculation operation (CAL) is prolonged, data coherency may be ensured because a data update becomes possible one period later.

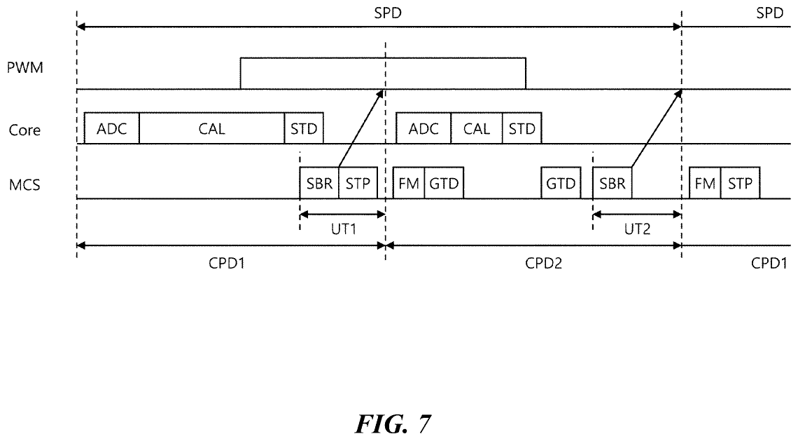

FIG. 7 is a diagram illustrating a second example of performing double-sampling control in an inverter, according to an embodiment.

Referring to FIG. 7, the core may repeatedly perform ADC, CAL, and STD in each of the control periods CPD1 and CPD2.

Here, when the calculation operation (CAL) is prolonged in any one control period, the operation of updating the new-data variable (STD) may be completed later than the start time point of the update interval. In the example of FIG. 7, this phenomenon occurs in the first control period CPD1.

In this case, the MCS may first update the register with the value of the buffer-data variable (SBR) in the update interval UT1 of the control period CPD1. In addition, the MCS may perform the operation of storing, in the previous-data variable, the value of the buffer-data variable (STP), in the update interval UT1 of the corresponding control period. In addition, in the next control period CPD2, after performing the flag management logic FM, the MCS may perform the operation of storing, in the buffer-data variable, the value stored in the new-data variable within the shared memory (GTD).

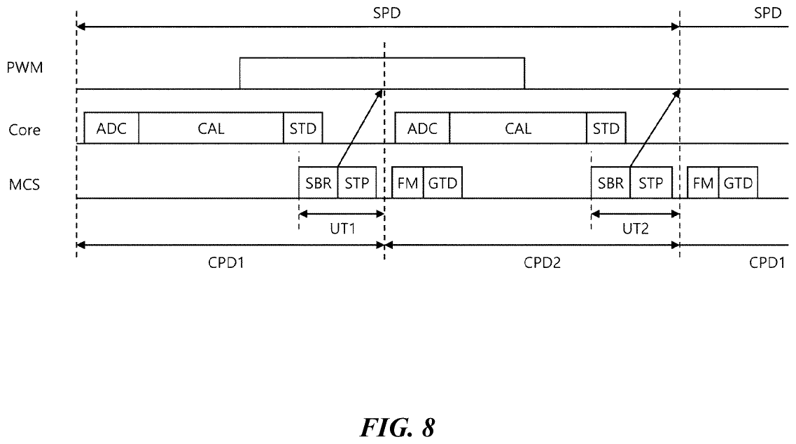

FIG. 8 is a diagram illustrating a third example of performing double-sampling control in an inverter, according to an embodiment.

Referring to FIG. 8, the core may repeatedly perform ADC, CAL, and STD in each of the control periods CPD1 and CPD2.

Here, when the calculation operation (CAL) is prolonged in each of the two control periods CPD1 and CPD2 of a single switching period SPD, the operation of updating the new-data variable (STD) may be completed later than the start time points of the respective update intervals.

In this case, the MCS may first update the register with the value of the buffer-data variable (SBR), in the update intervals UT1 and UT2 of the control periods CPD1 and CPD2, respectively. In addition, the MCS may perform the operation of storing, in the previous-data variable, the value of the buffer-data variable (STP), in the update intervals UT1 and UT2 of the respective control periods. In addition, in the next control period, after performing the flag management logic FM, the MCS may perform the operation of storing, in the buffer-data variable, the value stored in the new-data variable within the shared memory (GTD).

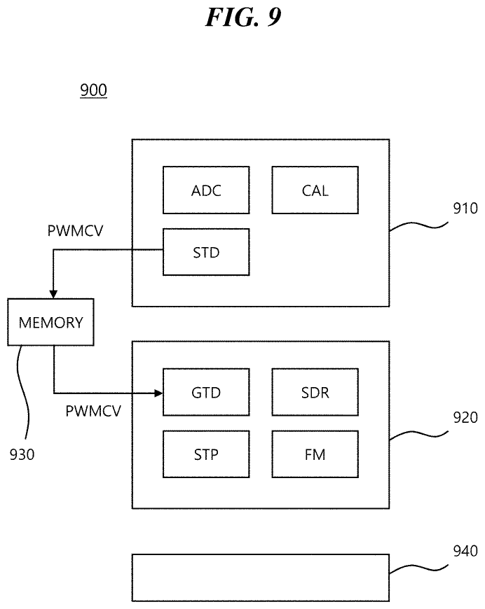

FIG. 9 is a configuration diagram of an inverter control apparatus according to an embodiment.

Referring to FIG. 9, the inverter control apparatus may include a core 910, an MCS 920, a shared memory 930, a PWM control circuit 940, and the like.

The core 910 may include, or may otherwise be configured to execute, an ADC sensing logic ADC, a calculation logic CAL, and a data sharing logic STD.

The ADC sensing logic ADC may obtain an ADC sampling value by driving an ADC circuit. Alternatively, the ADC sensing logic ADC may obtain an ADC sampling value, which has been generated elsewhere, by using communication or the like.

The calculation logic CAL may calculate a switching PWM control value PWMCV by using the ADC sampling value.

Then, the data sharing logic STD may store the switching PWM control value PWMCV, which has been calculated by the calculation logic CAL, in the shared memory 930. For example, the data sharing logic STD may store the switching PWM control value PWMCV in a new-data variable within the shared memory 930. In addition, the data sharing logic STD may manage a data counter to confirm whether a sufficient time exists between the time point at which the switching PWM control value PWMCV is stored in the shared memory 930 and the time point at which the MCS 920 updates the register. For example, after storing the switching PWM control value PWMCV in the new-data variable of the shared memory 930, the data sharing logic STD may increment the data counter.

The MCS 920 may include a data obtaining logic GTD, an update logic SDR, a previous-data setting logic STP, a flag management logic FM, and the like.

The data obtaining logic GTD may read the switching PWM control value PWMCV from the shared memory 930. The data obtaining logic GTD, while checking the value of the data counter, may read the value of the new-data variable from the shared memory 930, when the value of the data counter is different from the value of a previous-data counter. Then, the data obtaining logic GTD may store the value of the new-data variable in a buffer-data variable. When the value of the new-data variable is successfully transferred to the buffer-data variable in this manner, the data obtaining logic GTD may store the value of the data counter in the previous-data counter.

The update logic SDR may include a buffer-data update logic that updates the register with the value of the buffer-data variable (refer to SBR in the above description), and a previous-data update logic that updates the register with the value of the previous-data variable (refer to SPR in the above description). In addition, the update logic SDR may selectively execute SBR and SPR.

The previous-data setting logic STP and the flag management logic FM, according to embodiments, are described in more detail below.

In addition, the PWM control circuit 940 may output a switching PWM signal, which controls the inverter, by using values in the register.

The MCS 920 may divide each switching PWM period into a first control period and a second control period, and execute the update logic SDR in a predetermined time interval (the above-described update interval) in each of the first control period and the second control period.

When the core 910 executes the calculation logic CAL once in each switching PWM period, the update logic SDR may update, in the first control period, the register with the value of the previous-data variable and may update, in the second control period, the register with the value of the buffer-data variable.

The MCS 920 may execute the update logic SDR once in each control period, and execute the data obtaining logic GTD by using a polling technique where the value of the data counter is checked at regular time intervals.

When storing the switching PWM control value PWMCV in the new-data variable, the data sharing logic STD may set the value of a status variable in the shared memory to a first value. The first value may be, for example, a value (e.g., 0) that signifies ‘Writing’.

In addition, when storing the value of the new-data variable in the buffer-data variable, the data obtaining logic GTD may set the value of the status variable to a second value. The second value may be, for example, a value (e.g., 1) that signifies ‘Reading_Completed’.

The update logic SDR may update the register with the value of the previous-data variable when the value of the status variable is the first value, and may update the register with the value of the buffer-data variable when the value of the status variable is the second value.

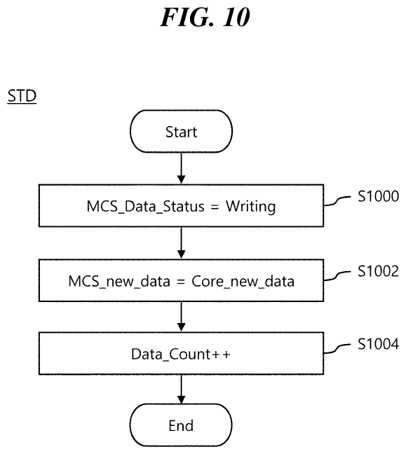

FIG. 10 is a flowchart of a data sharing logic according to an embodiment.

Referring to FIG. 10, in an operation S1000, the data sharing logic STD may set the value of a status variable MCS_Data_Status to a first value (‘Writing’).

In an operation S1002, the data sharing logic STD may store a switching PWM control value Core_new_data in a new-data variable MCS_new_data.

In an operation S1004, the data sharing logic STD may increment the value of a data counter Data_Count.

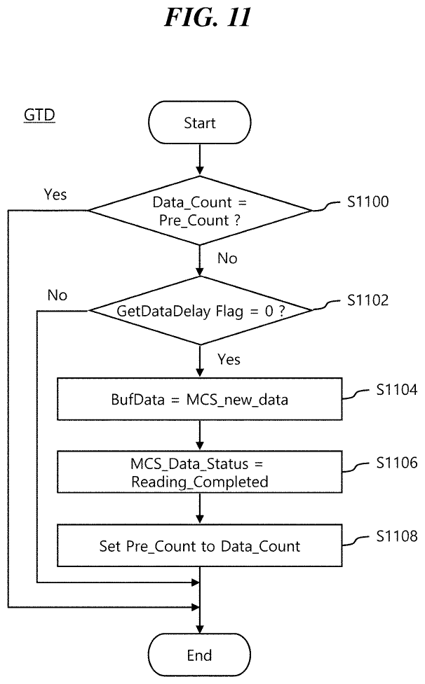

FIG. 11 is a flowchart of a data obtaining logic according to an embodiment.

Referring to FIG. 11, in an operation S1100, the data obtaining logic GTD may compare the value of the data counter Data_Count with the value of a previous-data counter Pre_Count. When the value of the data counter Data_Count is equal to the value of the previous-data counter Pre_Count (‘Yes’ in the operation S1100), the procedure may be terminated without performing the subsequent processes.

In an operation S1102, the data obtaining logic GTD may check the value of a data-obtaining flag GetDataDelay Flag. The data obtaining logic GTD may thus check both i) the value of the data counter Data_Count in the operation S1100 and ii) the value of a data-obtaining flag GetDataDelay Flag in the operation S1102.

When the value of the data counter Data_Count is different from the value of the previous-data counter Pre_Count (‘No’ in the operation S 1100), and the value of the data-obtaining flag GetDataDelay Flag is different from a third value (e.g., 1) or is equal to an opposite value of the third value (e.g., 0) (‘Yes’ in the operation S1102), the data obtaining logic GTD may store the value of the new-data variable MCS_new_data in a buffer-data variable BufData in an operation S1104.

In an embodiment, the data-obtaining flag GetDataDelay Flag may be set to the third value by the update logic, and for example, the update logic may set the data-obtaining flag GetDataDelay Flag to the third value when the value of the status variable is the first value.

In an operation S1106, after storing the value of the new-data variable MCS_new_data in the buffer-data variable BufData, the data obtaining logic GTD may set the value of the status variable MCS_Data_Status to the second value.

In an operation S1108, the data obtaining logic GTD may set the value of the previous-data counter Pre_Count to be equal to the value of the data counter Data_Count.

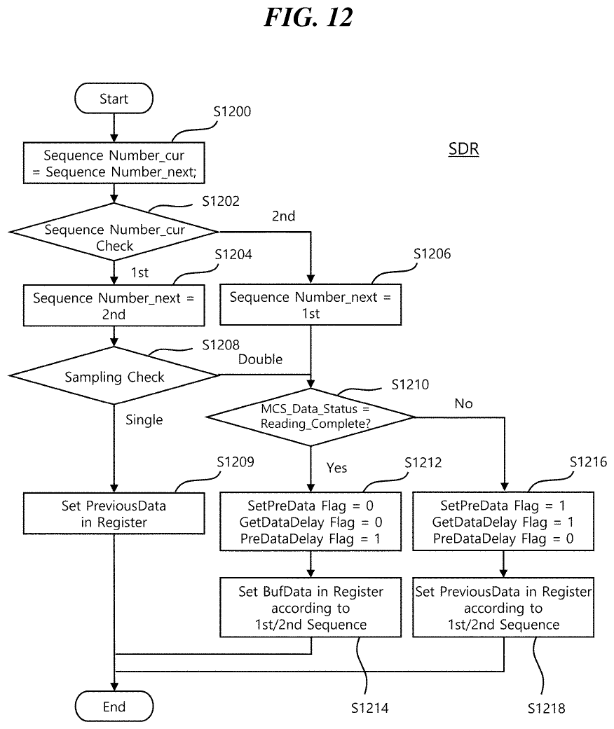

FIG. 12 is a flowchart of an update logic according to an embodiment.

Referring to FIG. 12, in the operation S1200, the update logic SDR may copy the value of a variable Sequence Number_next, which identifies a next control period, to a variable Sequence Number_cur, which identifies a current control period.

In an operation S1202, the update logic SDR may check the variable Sequence Number_cur that identifies the current control period.

When the variable Sequence Number_cur that identifies the current control period indicates a first control period (‘1st’ in the operation S1202), the update logic SDR may, in an operation S1204, modify the variable Sequence Number_next, which identifies the next control period, to indicate a second control period. In addition, when the variable Sequence Number_cur that identifies the current control period indicates the second control period (‘2nd’ in the operation S1202), the update logic SDR may, in an operation S1206, modify the variable Sequence Number_next, which identifies the next control period, to indicate the first control period.

In an operation S1208, when the current control period is the first control period, the update logic SDR may check whether the number of times of sampling is set to 1 or 2. When the number of times of sampling is set to 1 (‘Single’ in the operation S1208), the update logic SDR may, in an operation S1209, update the register with the value of the previous-data variable, in the first control period. On the other hand, when the number of times of sampling is set to 2 (‘Double’ in the operation S1208), the update logic SDR may, in an operation S1210, check the value of the status variable MCS_Data_Status, in the first control period.

In both the case where the current control period is the first control period and the number of times of sampling is set to 2 (‘Double’ in the operation S1208), and the case where the variable Sequence Number_cur that identifies the current control period indicates the second control period (‘2nd’ in the operation S1202), the same logic may be subsequently performed.

First, in an operation S1210, the update logic SDR may check the value of the status variable MCS_Data_Status.

When the value of the status variable MCS_Data_Status is the second value (e.g., ‘Reading_Complete’) (‘Yes’ in the operation S1210), the update logic SDR may set a set-previous-data flag SetPreData Flag to an eighth value (e.g., 0), set the data-obtaining flag GetDataDelay Flag to a fourth value (e.g., 0), and set a previous-data delay flag PreDataDelay Flag to a fifth value (e.g., 1) in an operation S1212.

In addition, when the value of the status variable MCS_Data_Status is the second value (e.g., ‘Reading_Complete’) (‘Yes’ in S1210), the update logic SDR may, in an operation S1214, update the register with the value of the buffer-data variable.

When the value of the status variable MCS_Data_Status is the first value (e.g., ‘Writing’) (‘No’ in the operation S1210), the update logic SDR may, in an operation S1216, set the set-previous-data flag SetPreData Flag to a seventh value (e.g., 1), set the data-obtaining flag GetDataDelay Flag to the third value (e.g., 1), and set the previous-data delay flag PreDataDelay Flag to a sixth value (e.g., 0).

In addition, when the value of the status variable MCS_Data_Status is the first value (e.g., ‘Writing’) (‘No’ in the operation S1210), the update logic SDR may, in an operation S1218, update the register with the value of the previous-data variable.

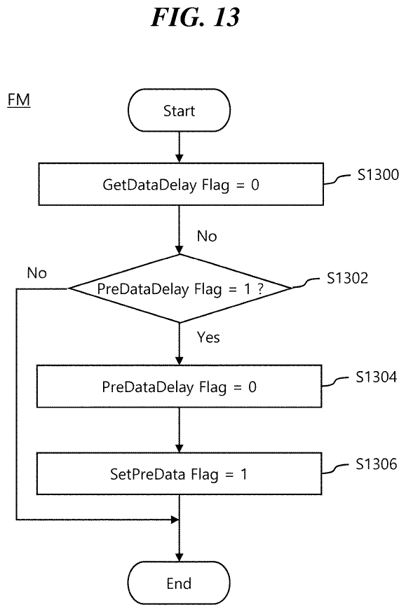

FIG. 13 is a flowchart of a flag management logic according to an embodiment.

Referring to FIG. 13, in an operation S1300, the flag management logic FM may set the value of the data-obtaining flag GetDataDelay Flag to the fourth value (e.g., 0), which is different from the third value (e.g., 1).

The MCS may divide each switching PWM period into a first control period and a second control period, and execute the flag management logic FM within a certain time period from the start time point of each control period.

In an operation S1302, the flag management logic FM may check the previous-data delay flag PreDataDelay Flag. When the previous-data delay flag PreDataDelay Flag is the fifth value (e.g., 1) (‘Yes’ in the operation S1302), the flag management logic FM may, in an operation S1304, set the previous-data delay flag PreDataDelay Flag to a sixth value (e.g., 0), Also, the flag management logic FM may, in an operation S1306, set the set-previous-data flag SetPreData Flag to the seventh value (e.g., 1).

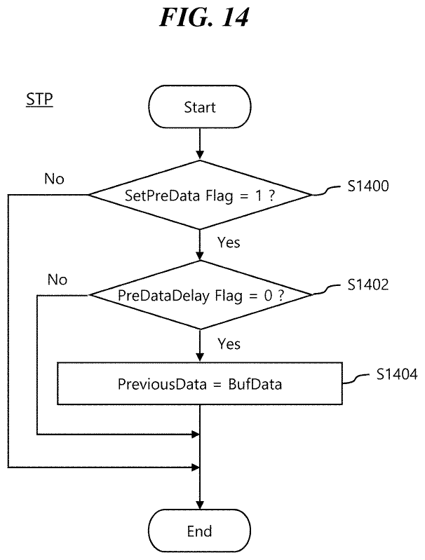

FIG. 14 is a flowchart of a previous-data setting logic according to an embodiment.

Referring to FIG. 14, in an operation S1400, the previous-data setting logic STP may check the set-previous-data flag SetPreData Flag.

When the set-previous-data flag SetPreData Flag is the seventh value (e.g., 1) (‘Yes’ in the operation S1400), the previous-data setting logic STP may, in an operation S1402, check the previous-data delay flag PreDataDelay Flag.

When the previous-data delay flag PreDataDelay Flag is the sixth value (e.g., 0) (‘Yes’ in the operation S1402), the previous-data setting logic STP may, in an operation S1404, store the value of the buffer-data variable in the previous-data variable.

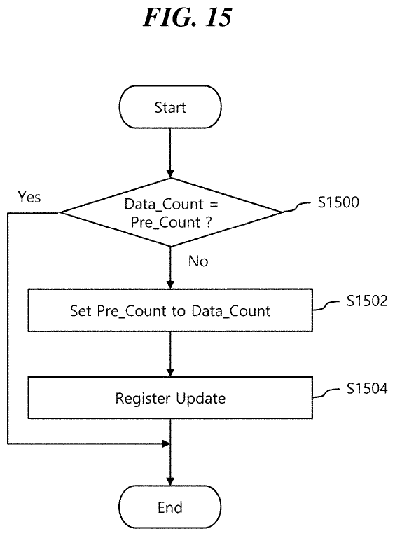

FIG. 15 is a flowchart of a data processing method of an MCS according to an embodiment.

Referring to FIG. 15, in an operation S1500, the MCS may check the data counter Data_Count, which is incremented by a core configured to calculate a switching PWM control value by using an ADC sampling value for an inverter, after the core stores a switching PWM control value in the new-data variable within the shared memory.

When the value of the data counter Data_Count is different from the value of the previous-data counter Pre_Count (‘No’ in the operation S1500), the MCS may, in an operation S1502, store the value of the new-data variable in the buffer-data variable, and store the value of the data counter Data_Count in the previous-data counter Pre_Count.

In an operation S1504, the MCS may update the register with the value of the buffer-data variable or the value of the previous-data variable, which stores a previous value of the buffer-data variable.

Each switching PWM period may be divided into a first control period and a second control period, and a predetermined update interval may be allocated to each control period. In addition, in the update interval, the MCS may update the register with the value of the buffer-data variable or the value of the previous-data variable.

In addition, when the core obtains an ADC sampling value only once in each switching PWM period, the MCS may, in the operation S1504, update the register with the value of the previous-data variable, in the first control period, and update the register with the value of the buffer-data variable, in the second control period.

In various embodiments, the core may divide each switching PWM period into a first control period and a second control period, and in each control period, the core may execute a calculation logic that calculates a switching PWM control value by using an ADC sampling value for an inverter, and a data sharing logic that stores the switching PWM control value in a new-data variable of a shared memory.

In addition, the MCS may execute a data obtaining logic that stores the value of the new-data variable in a buffer-data variable, and an update logic that updates the register in a predetermined update interval in each control period, wherein when the time point of updating the new-data variable is earlier than the start time point of the update interval, the update logic may update the register with the value of the buffer-data variable, and when the time point of updating the new-data variable is later than the start time point of the update interval, the update logic may update the register with the value of the previous-data variable, which is storing a previous value of the buffer-data variable.

When the update logic updates the register with the value of the previous-data variable, the MCS may execute the data obtaining logic in the next control period.

In addition, when the update logic updates the register with the value of the previous-data variable, the MCS may execute a set-previous-data logic that stores the value of the buffer-data variable in the previous-data variable, in the corresponding update interval.

In addition, the core may increment a data counter after the data sharing logic stores the switching PWM control value in the new-data variable within the shared memory, and the MCS may determine the time point of updating the new-data variable by comparing the value of the data counter with the value of a previous-data counter, which stores a previous value of the data counter.

The MCS may execute the update logic once in each control period, and execute the data obtaining logic by using a polling technique where the value of the data counter is checked at regular time intervals.

As described above, according to an embodiment of the present disclosure, an inverter may maintain data coherency in any case. Furthermore, according to an embodiment of the present disclosure, data coherency may be ensured in an inverter in which double sampling is performed.

The terms such as “include,” “comprise,” or “have” described above mean that the corresponding component may be inherent as long as there is no particular opposing recitation, and thus, it should be interpreted that other components may be further included rather than excluded. All terms used herein, including technical and scientific terms, have the same meaning as commonly understood by those of ordinary skill in the art, unless defined otherwise. Terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

The above description merely explains the technical idea of the present disclosure, and the present disclosure may be changed and modified by those of ordinary skill in the art in various ways without departing from the scope of the present disclosure. Accordingly, the embodiments described herein are provided not to limit, but to merely explain the technical idea of the present disclosure, and the technical idea of the present disclosure is not limited by the described embodiments. The scope of the present disclosure should be construed by the following claims, and all technical ideas within the equivalent scope should be construed as being included in the scope of the present disclosure.

What is claimed is:

1. An inverter control apparatus comprising:
a core configured to:
execute a calculation logic configured to calculate a switching pulse-width modulation (PWM) control value by using an analog-to-digital converter (ADC) sampling value for an inverter, and
execute a data sharing logic configured to store the switching PWM control value in a new-data variable in a shared memory and then increment a data counter;
a multichannel sequencer configured to:
execute a data obtaining logic configured to, based on determining that a value of the data counter is different from a value of a previous-data counter, store the value of the new-data variable in a buffer-data variable and store the value of the data counter in the previous-data counter, and
execute an update logic configured to update a register with a value of the buffer-data variable or a value of a previous-data variable, wherein the previous-data variable stores a previous value of the buffer-data variable; and
a PWM control circuit configured to output a switching PWM signal to control the inverter by using a value of the register.

2. The inverter control apparatus of claim 1, wherein the multichannel sequencer is further configured to:
divide each switching PWM period into a first control period and a second control period; and
execute the update logic in a predetermined time interval of each of the first control period and the second control period.

3. The inverter control apparatus of claim 2, wherein, when the core executes the calculation logic once in each switching PWM period, the update logic updates, in the first control period, the register with the value of the previous-data variable, and updates, in the second control period, the register with the value of the buffer-data variable.

4. The inverter control apparatus of claim 2, wherein the multichannel sequencer is further configured to:
execute the update logic once in each control period, and
execute the data obtaining logic by using a polling technique in which the value of the data counter is checked at regular time intervals.

5. The inverter control apparatus of claim 1, wherein:
the data sharing logic is configured to, when storing the switching PWM control value in the new-data variable, set a value of a status variable located in the shared memory to a first value;
the data obtaining logic is configured to, when storing the value of the new-data variable in the buffer-data variable, set the value of the status variable to a second value; and
the update logic is configured to:
when the value of the status variable is the first value, update the register with the value of the previous-data variable, and
when the value of the status variable is the second value, update the register with the value of the buffer-data variable.

6. The inverter control apparatus of claim 5, wherein:
the update logic is configured to, when the value of the status variable is the first value, set a data-obtaining flag to a third value, and
the data obtaining logic is configured to:
check the value of the data counter and the value of the data-obtaining flag, and
when the value of the data counter is different from the value of the previous-data counter and the value of the data-obtaining flag is different from the third value, store the value of the new-data variable in the buffer-data variable.

7. The inverter control apparatus of claim 6, wherein the multichannel sequencer is further configured to execute a flag management logic configured to set the value of the data-obtaining flag to a fourth value that is different from the third value.

8. The inverter control apparatus of claim 7, wherein the multichannel sequencer is further configured to:
divide each switching PWM period into a first control period and a second control period; and
execute the flag management logic within a predetermined time period from a start time point of each control period.

9. The inverter control apparatus of claim 5, wherein:
the update logic is configured to, when the value of the status variable is the first value, set a set-previous-data flag to a seventh value; and
the multichannel sequencer is further configured to, when the set-previous-data flag is the seventh value, execute a set-previous-data logic configured to store the value of the buffer-data variable in the previous-data variable.

10. An inverter control apparatus comprising:
a core configured to:
divide each switching pulse-width modulation (PWM) period into a first control period and a second control period, and
in each of the first control period and the second control period,
execute a calculation logic configured to calculate a switching PWM control value by using an analog-to-digital converter (ADC) sampling value for an inverter, and
execute a data sharing logic that stores the switching PWM control value in a new-data variable in a shared memory;
a multichannel sequencer configured to:
execute a data obtaining logic configured to store a value of the new-data variable in a buffer-data variable, and
execute an update logic configured to update a register in a predetermined update interval in each of the first control period and the second control period,
wherein the update logic is configured to:
when a time point of updating the new-data variable is earlier than a start time point of the predetermined update interval, update the register with a value of the buffer-data variable, and
when the time point of updating the new-data variable is later than the start time point of the predetermined update interval, update the register with a value of a previous-data variable storing a previous value of the buffer-data variable; and
a PWM control circuit configured to output a switching PWM signal to control the inverter by using a value of the register.

11. The inverter control apparatus of claim 10, wherein the multichannel sequencer is further configured to, when the update logic updates the register with the value of the previous-data variable, execute the data obtaining logic in a next control period.

12. The inverter control apparatus of claim 11, wherein the multichannel sequencer is further configured to, when the update logic updates the register with the value of the previous-data variable, execute a set-previous-data logic configured to store the value of the buffer-data variable in the previous-data variable, in a corresponding update interval.

13. The inverter control apparatus of claim 10, wherein:
the core is further configured to increment a data counter after the data sharing logic stores the switching PWM control value in the new-data variable in the shared memory; and
the multichannel sequencer is further configured to determine the time point of updating the new-data variable, by comparing the value of the data counter with a value of a previous-data counter that stores a previous value of the data counter.

14. The inverter control apparatus of claim 13, wherein the multichannel sequencer is further configured to:
execute the update logic once in each control period, and
execute the data obtaining logic by using a polling technique in which the value of the data counter is checked at regular time intervals.

15. A method of multichannel sequencing in an inverter control apparatus that outputs a switching pulse-width modulation (PWM) signal that controls an inverter by using a value of a register, the method comprising:
checking a data counter that is incremented by a core configured to calculate a switching PWM control value by using an analog-to-digital converter (ADC) sampling value for the inverter, wherein the data counter is incremented after the core stores the switching PWM control value in a new-data variable of a shared memory;
based on a determination that a value of the data counter is different from a value of a previous-data counter, storing a value of the new-data variable in a buffer-data variable and storing the value of the data counter in the previous-data counter; and
updating the register with a value of the buffer-data variable or a value of a previous-data variable that stores a previous value of the buffer-data variable.

16. The method of claim 15, wherein each switching PWM period is divided into a first control period and a second control period,
a predetermined update interval is allocated to each control period, and
in the predetermined update interval, the register is updated with the value of the buffer-data variable or the value of the previous-data variable.

17. The method of claim 16, wherein, based on that the core obtains the ADC sampling value only once in each switching PWM period, updating the register includes updating, in the first control period, the register with the value of the previous-data variable, and updating, in the second control period, the register with the value of the buffer-data variable.
